(19) United States
(12) Patent Application Publication
(10) Pub. No.: US 2025/0226313 A1
(43) Pub. Date: Jul. 10, 2025

(54) INTERCONNECT LINES WITH LINE WIDTH PROFILE

(71) Applicant: INTERNATIONAL BUSINESS MACHINES CORPORATION, ARMONK, NY (US)

(72) Inventors: James P. Mazza, Saratoga Springs, NY (US); Nicholas Anthony Lanzillo, Wynantskill, NY (US); Reinaldo Vega, Mahopac, NY (US); Takashi Ando, Eastchester, NY (US); David Wolpert, Poughkeepsie, NY (US)

(21) Appl. No.: 18/408,761

(22) Filed: Jan. 10, 2024

(51) Int. Cl. H01L 23/528; H01L 21/768; H01L 23/532

(52) U.S. Cl. CPC H01L 23/5283; H01L 21/76816; H01L 21/76882; H01L 21/76843; H01L 23/53238; H01L 23/53295

(57) ABSTRACT

Embodiments of present invention provide a semiconductor structure. The semiconductor structure includes a metal level that includes a metal line, the metal line includes a bottom section having a first width, a middle section having a second width, and a top section having a third width, where the second width of the middle section is narrower than the first width of the bottom section and is narrower than the third width of the top section. A method of forming the semiconductor structure is also provided.

### BACKGROUND

The present application relates to manufacturing of semiconductor integrated circuits. More particularly, it relates to method of forming metal lines of an interconnect structure with line width profile and the structure formed thereby.

A semiconductor integrated circuit such as a semiconductor chip generally includes a front-end-of-line (FEOL) region, where active device such as transistors are formed, and a back-end-of-line (BEOL) region, where power supplies and interconnect are provided to the active devices formed in the FEOL region. In instances, a middle-of-line (MOL) region may exist between the FEOL region and the BEOL region where contacts and/or local interconnects may be formed for the active devices in the FEOL region.

The BEOL region generally includes multiple metal lines such as metal level-1 (M1), metal level-2 (M2), . . . metal level-N (MN) and different metal levels may be inter-connected through various types of via structures between the metal lines. Generally, performance of lower metal levels such as, for example, M1 and M2 with a tight pitch such as a sub-36 nm pitch are resistance-dominated. On the other hand, upper metal lines such as those metal levels with a pitch equal to or larger than 80 nm are capacitance-dominated. In other words, resistance of the upper metal lines are usually not a concern, but it is the capacitance of those upper metal lines that often affect the performance of the semiconductor chip. Therefore, there is a need to improve the device performance by reducing the capacitance of upper metal lines.

### SUMMARY

Embodiments of present invention provide a semiconductor structure. The semiconductor structure includes a metal level that includes a metal line, the metal line includes a bottom section having a first width, a middle section having a second width, and a top section having a third width, where the second width of the middle section is narrower than the first width of the bottom section and is narrower than the third width of the top section.

In one embodiment, the semiconductor structure further includes a liner conformally lining sidewalls of the top section, sidewalls of the middle section, sidewalls of the bottom section, and a bottom surface of the bottom section.

In one embodiment, the metal line includes copper and the liner includes titanium-nitride (TiN).

In another embodiment, the bottom section is embedded in a first dielectric layer, the middle section is embedded in a second dielectric layer, and the top section is embedded in a third dielectric layer, where the second dielectric layer has a material composition that is different from material compositions of the first and the third dielectric layer.

In yet another embodiment, the second dielectric layer has an etch selectivity that is different from etch selectivity of the first and the third dielectric layer.

According to one embodiment, the metal line is a first metal line, and the semiconductor structure further includes a second metal line parallel to the first metal line, where a first horizontal distance between the middle section of the first metal line and a middle section of the second meta line is larger than a second horizontal distance between the top section of the first metal line and a top section of the second metal line.

In one embodiment, the second metal line, from a top to a bottom thereof, has a substantially uniform width.

In another embodiment, the middle section of the second metal line is narrower than the top section of the second metal line.

Embodiments of present invention further provide an interconnect structure. The interconnect structure includes a metal level including a metal line, the metal line includes a first section having a first width and a second section having a second width, the second section being directly on top of the first section; and a liner lining a bottom surface and sidewalls of the first section and lining sidewalls of the second section, where the first width of the first section is narrower than the second width of the second section.

In one embodiment, the metal line is a first metal line, the interconnect structure further includes a second metal line parallel to the first metal line, the second metal line having a first section and a second section, the second section of the second metal line being directly on top of the first section of the second metal line, where a first horizontal distance between the first section of the first metal line and the first section of the second meta line is larger than a second horizontal distance between the second section of the first metal line and the second section of the second metal line.

Embodiments of present invention provide a method of forming a semiconductor structure. The method includes forming a first dielectric layer on top of a supporting structure; forming a second dielectric layer on top of the first dielectric layer; forming a third dielectric layer on top of the second dielectric; creating an opening that has a first area in the first dielectric layer, a second area in the second dielectric layer, and a third area in the third dielectric layer; selectively etching the first and the third dielectric layer, relative to the second dielectric layer, thereby horizontally expanding the first area and the third area of the opening respectively to create an expanded opening; and filling the expanded opening with a conductive material to form a metal line, where the metal line has a bottom section with a first width, a middle section with a second width, and a top section with a third width, the second width being smaller than the first width and the third width.

### BRIEF DESCRIPTION OF THE DRAWINGS

The present invention will be understood and appreciated more fully from the following detailed description of embodiments of present invention, taken in conjunction with accompanying drawings of which:

FIGS. 1A-1E are demonstrative illustrations of cross-sectional views of a semiconductor structure at various steps of manufacturing thereof according to one embodiment of present invention;

FIGS. 2A-2H are demonstrative illustrations of cross-sectional views of a semiconductor structure at various steps of manufacturing thereof according to another embodiment of present invention;

FIG. 3 is a demonstrative illustration of cross-sectional views of a semiconductor structure according to one embodiment of present invention;

FIG. 4 is a demonstrative illustration of cross-sectional views of a semiconductor structure according to another embodiment of present invention;

FIG. 5 is a demonstrative illustration of cross-sectional views of a semiconductor structure according to yet another embodiment of present invention; and

FIG. 6 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

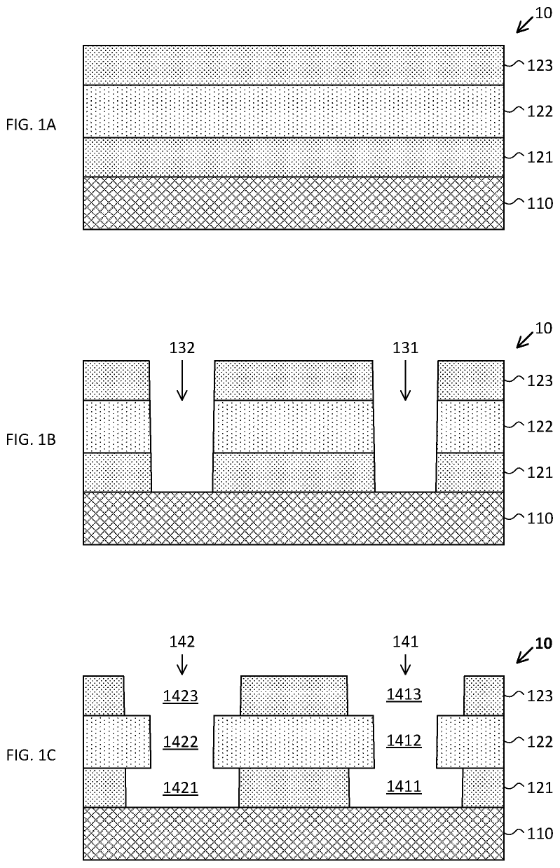

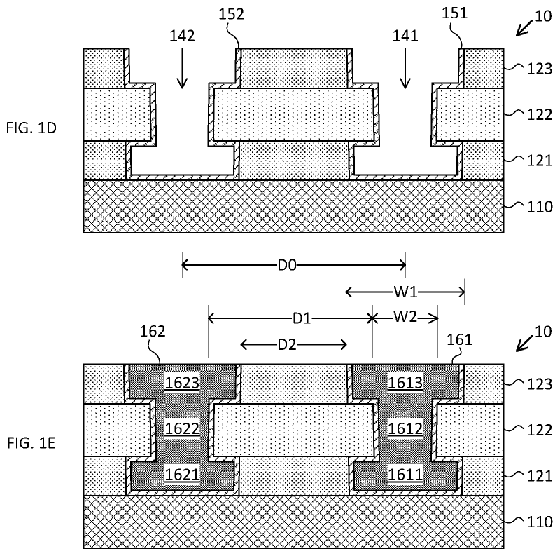

FIGS. 1A-1E are demonstrative illustrations of cross-sectional views of a semiconductor structure 10 at various steps of manufacturing thereof according to one embodiment of present invention. More particularly, with reference to FIG. 1A, embodiments of present invention provide forming the semiconductor structure 10 by receiving or providing a supporting structure 110; forming a first dielectric layer 121 on top of the supporting structure 110, forming a second dielectric layer 122 on top of the first dielectric layer 121; and forming a third dielectric layer 123 on top of the second dielectric layer 122. The supporting structure 110 may be a substrate such as a silicon substrate, a silicon-germanium substrate, or a silicon-on-insulator (SOI) substrate; may be an interconnect structure or a lower portion of an interconnect structure; or may be another dielectric layer. The semiconductor structure 10 may be an interconnect structure.

The first, second, and third dielectric layers 121, 122, and 123 may be made of, for example, silicon-oxide (SiO₂), silicon-nitride (SiN), silicoboron-carbonitride (SiBCN), silicon-oxycarbonitride (SiOCN), or other low-k dielectric materials. More particularly, the second dielectric layer 122 may have a material composition that is different from material composition of the first dielectric layer 121 and the third dielectric layer 123 such that they have different etch selectivity or exhibit different etch selectivity during a selective etch process. For example, the second dielectric layer 122 may be SiN, and the first and the third dielectric layer 121 and 123 may be SiBCN. The SiBCN material of the first and the third dielectric layer 121 and 123 may be etched selective to the SiN material of the second dielectric layer 122. Further for example, the second dielectric layer 122 may be SiN and the first and the third dielectric layer may be SiO₂. The first, the second, and the third dielectric layers 121, 122, and 123 may be formed through deposition by a physical-vapor-deposition (PVD) process, a chemical-vapor-deposition (CVD) process, an atomic-layer-deposition (ALD) process, or other currently existing or future developed processes.

With reference to FIG. 1B, embodiments of present invention provide creating one or more openings, such as a first opening 131 and a second opening 132, through the first, the second, and the third dielectric layer 121, 122, and 123. For example, a mask layer (not shown) may first be formed on top of the stack of dielectric layers such as on top of the third dielectric layer 123; one or more openings may then be created in the mask layer through, for example, a lithographic patterning process. Next, the one or more openings may be transferred onto the underneath dielectric layers through, for example, an anisotropic or directional etch process such as a reactive-ion-etch (RIE) process to create the first and the second openings 131 and 132.

With reference to FIG. 1C, embodiments of present invention provide horizontally expanding selective areas of the first opening 131 and the second opening 132 to create an expanded first opening 141 and an expanded second opening 142. More particularly, by strategically applying differences in etch selectivity among the first, the second, and the third dielectric layer 121, 122, and 123, a first area of the first opening 131 may be horizontally expanded through a selective etch process in the first dielectric layer 121 to create an expanded first area 1411 and a third area of the first opening 131 may be horizontally expanded through a selective etch process in the third dielectric layer 123 to create an expanded third area 1413. In the meantime, a second area of the first opening 131 may remain substantially un-affected or un-etched as a second area 1412. For example, with the first and the third dielectric layer 121 and 123 being SiO₂ and the second dielectric layer 122 being SiN, a selective etch process may be used to etch the first and the third dielectric layer 121 and 123.

Similarly, a first and a third area of the second opening 132 may be horizontally expanded to form the expanded second opening 142 having an expanded first area 1421, a second area 1422, and an expanded third area 1423.

With reference to FIG. 1D, embodiments of present invention provide forming liners lining inner surfaces, such as sidewalls and bottoms, of the expanded first and second openings 141 and 142. For example, a first liner 151 may be formed, for example through an ALD process, to conformally line an exposed portion or top surface of the supporting structure 110 and sidewalls of the first, the second, and the third dielectric layer 121, 122, and 123 of the expanded first opening 141. The first liner 151 may be a layer of titanium (Ti), titanium-nitride (TiN), tantalum (Ta), tantalum-nitride (TaN), cobalt (Co), rutherium (Ru), or other suitable material. The first liner 151 may be formed as a barrier layer to prevent metal contamination of the surrounding dielectric materials.

Similarly, a second liner 152 may be conformally formed to line the expanded second opening 142 at sidewalls of the first, the second, and the third dielectric layer 121, 122, and 123 and the exposed top surface of the supporting structure 110.

With reference to FIG. 1E, embodiments of present invention provide filling the expanded first and second openings 141 and 142 with a conductive material to form a first metal line 161 and a second metal line 162 respectively. The first and the second metal line 161 and 162 may be part of a metal level in an interconnect structure. An interconnect structure may include multiple metal levels with each metal level including multiple metal lines. Metal lines in a metal level may be interconnected to metal lines in another metal level below or above current metal level through, for example, one or more conductive vias. The conductive vias are normally formed between different metal levels.

In one embodiment, the conductive material may include Co, Ru, tungsten (W), copper (Cu) or other suitable materials including alloyed material such as CoSi and CuAl. The conductive material may first be deposited into the expanded first and second openings 141 and 142 through, for example, a PVD process, a CVD process, an ALD process or a combination of the processes. Embodiments of present invention further provide subjecting the deposited conductive material to a metal reflow process to cause the conductive material to, for example, horizontally expand to substantially fill up the expanded first area 1411 of the expanded first opening 141, thereby forming a bottom section 1611 of the first metal line 161. The filled conductive material may also form a middle section 1612 and a top section 1613 of the first metal line 161.

Similarly, filling the conductive material in the expanded second opening 142, and subjecting the conductive material to a metal reflow process, may form the second metal line 162 that has a bottom section 1621, a middle section 1622, and a top section 1623.

In one embodiment, the bottom section 1611 of the first metal line 161 may have a first width, the middle section 1612 may have a second width, and the top section 1613 may have a third width and the second width may be narrower than the first width and the third width. For example, the bottom section and the top section may have a width W1 and the middle section may have a width W2. W2 may be smaller than W1 and, in one embodiment, W2 may be between about 25% and about 50% of W1. In another embodiment, the first width of the bottom section may be smaller than the third width of the top section due to the nature of etch process and/or difference in etch selectivity in material between the first and the third dielectric layer.

In another embodiment, the middle section 1612 of the first metal line 161 and the middle section 1622 of the second metal line 162 may be separated by a first horizontal distance D1. The top section 1613 of the first metal line 161 and the top section 1623 of the second metal line 162 may be separated by a second horizontal distance D2. D1 is larger than D2 and, in one embodiment, D1 may be between about 120% and about 140% of D2. By increasing the horizontal distance between the middle sections of the first and the second metal line 161 and 162, embodiments of present invention may be able to reduce a capacitance formed by the first and the second metal line 161 and 162 by up to 50%, depending upon a ratio of thicknesses of the middle section 1612 versus the bottom section 1611 and the top section 1613. In the meantime, a reduction in width of the middle section 1612 may increase resistance of the first metal line 161 but according to embodiments of present invention the increase would be acceptable when the reduction, expressed by the ratio W2/W1, is within 25% to 50%.

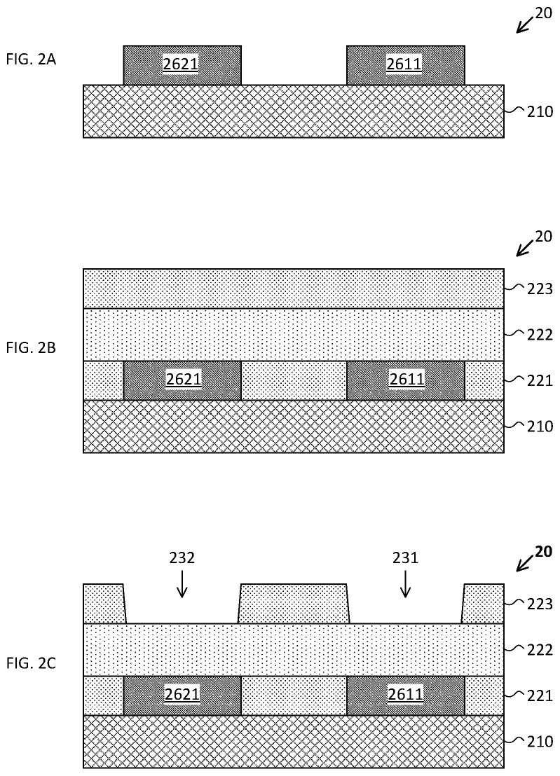

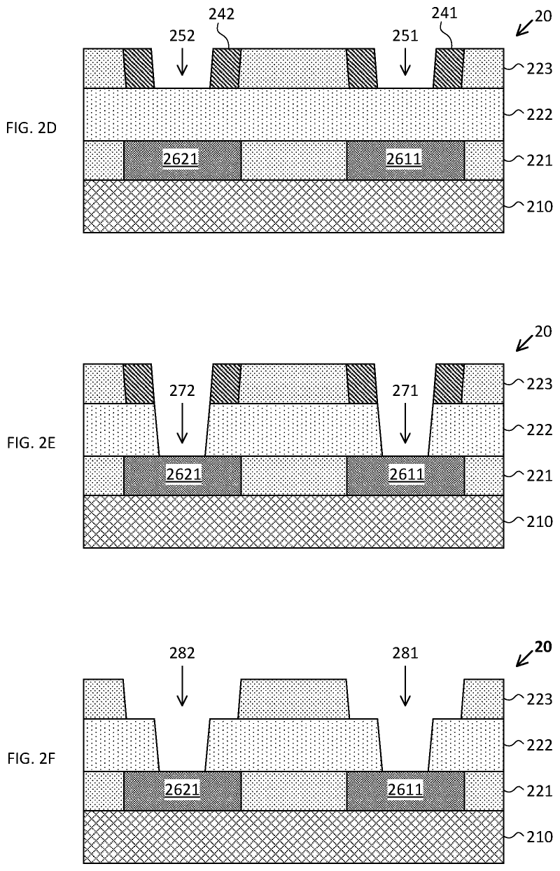

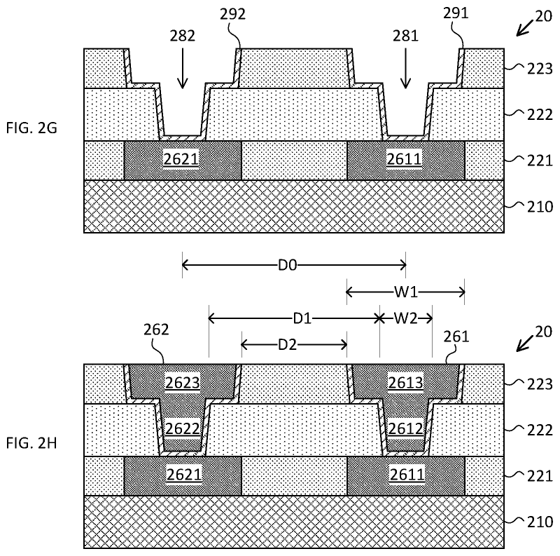

FIGS. 2A-2H are demonstrative illustrations of cross-sectional views of a semiconductor structure at various steps of manufacturing thereof according to another embodiment of present invention. More particularly, with reference to FIG. 2A, embodiments of present invention provide forming a semiconductor structure 20 by receiving or providing a supporting structure 210 and performing a metal deposition process to form a third section 2611 of a first metal line 261 (see FIG. 2H) and a third section 2621 of a second metal line 262 (see FIG. 2H) directly on top of the supporting structure 210. However, embodiments of present invention are not limited in this aspect. For example, in one embodiment, the third sections 2611 and 2621 are not formed directly on top of the supporting structure 210.

With reference to FIG. 2B, embodiments of present invention provide, upon forming the third sections 2611 and 2621, forming a first dielectric layer 221 on top of the supporting structure 210 covering the third sections 2611 and 2621. A chemical-mechanical-polishing (CMP) process may then be applied to planarize the first dielectric layer 221 until the third sections 2611 and 2621 are exposed. Embodiments of present invention further provide forming a second dielectric layer 222 on top of the first dielectric layer 221 through a deposition process and forming a third dielectric layer 223 on top of the second dielectric layer 222 through a deposition process as well. The first, the second, and the third dielectric layers 221, 222, and 223 may have different material compositions and thus different etch selectivity.

With reference to FIG. 2C, embodiments of present invention provide creating one or more openings in the third dielectric layer 223. More particularly, embodiments of present invention provide creating a first opening 231 and a second opening 232 in the third dielectric layer 223. For example, a mask layer may be formed on top of the third dielectric layer 223; openings may be created in the mask layer through a lithographic patterning process; and the openings may subsequently be transferred onto the third dielectric layer 223 through an anisotropic and/or directional etching process to create the first and the second openings 231 and 232. The first and the second openings 231 and 232 may expose a top surface of the second dielectric layer 222 and may be substantially aligned with the underneath third section 2611 of the first metal line 261 and third section 2621 of the second metal line 262 respectively.

With reference to FIG. 2D, embodiments of present invention provide forming sidewall spacers 241 in the first opening 231 and sidewall spacers 242 in the second opening 232. The sidewall spacers 241 and 242 may be conformal sidewall spacers and may be formed by first forming a conformal layer lining the semiconductor structure 20 and subsequently selectively removing horizontal portions of the conformal layer. The selective removal process leaves only vertical portions of the conformal layer at sidewalls of the third dielectric layer 223 to form the sidewall spacers 241 and 242.

The sidewall spacers 241 and 242 may be made of a dielectric material, which may have a material composition that is different from a material composition of the second dielectric layer 222 and may be different from a material composition of the third dielectric layer 223. The difference in material compositions of the sidewall spacers 241 and 242 and the second and the third dielectric layers 222 and 223 enables a selective etch process that may be strategically applied to create openings for forming metal lines. The sidewall spacer 241 may have a sufficient thickness such that they form or create a modified first opening 251 that has a reduced width than the first opening 231. Similarly, the sidewall spacer 242 may have a sufficient thickness as well, thereby forming or creating a modified second opening 252 that has a reduced width than the second opening 232 as well.

With reference to FIG. 2E, embodiments of present invention provide selectively etching the second dielectric layer 222 through the modified first opening 251 and the modified second opening 252 to create a first opening 271 and a second opening 272 in the second dielectric layer 222. The first and the second openings 271 and 272 may expose the third section 2611 and the third section 2621 of the first and the second metal line 261 and 262 respectively. In the event that the second dielectric layer 222 is formed directly on top of the supporting structure 210, without the third sections 2611 and 2621, the first and the second opening 271 and 272 may expose the underneath supporting structure 210.

With reference to FIG. 2F, embodiments of present invention provide selectively removing the sidewall spacers 241 and 242 to restore or re-create the first and the second opening 231 and 232 originally formed in the third dielectric layer 223. The first and the second opening 231 and 232 together with the first and the second opening 271 and 272 in the second dielectric layer 222 form a combined first opening 281 and a combined second opening 282. The combined first and second openings 281 and 282 may have a T-shaped cross-section and may expose the underneath third sections 2611 and 2621 or the supporting structure 210, depending on the embodiments.

With reference to FIG. 2G, embodiments of present invention provide forming a liner lining the combined first and second openings 281 and 282. More particularly, embodiments of present invention provide forming a first liner 291 lining the combined first opening 281 and a second liner 292 lining the combined second opening 282. The first and the second liner 291 and 292 may be made of Ti, TiN, Ta, TaN, Co, Ru, or other suitable materials, and may line sidewalls of the third dielectric layer 223, sidewalls of the second dielectric layer 222, and the exposed top surfaces of structure under the second dielectric layer 222. For example, the first and the second liner 291 and 292 may be directly on top of and in contact with the third sections 2611 and 2621 respectively.

With reference to FIG. 2H, embodiments of present invention provide filling the combined first and second openings 281 and 282, which are surrounded by the first and the second liner 291 and 292 respectively, with a conductor material to form the first metal line 261 and the second metal line 262. The first and the second metal line 261 and 262 may be part of a metal level, such as M9, M10, etc., and may each include a first section 2612 and 2622 respectively and a second section 2613 and 2623 respectively. In one embodiment, the first and the second metal line 261 and 262 may include the third section 2611 and 2621 respectively.

In one embodiment, for example, the second section 2613 of the first metal line 261 may have a first width W1 and the first section 2612 of the first metal line 261 may have a second width W2. W2 may be smaller than W1 and in one embodiment may be between about 25% and about 50% of W1. The third section 2611 and 2621 may have a third width that is wider than the first width W1 of the first section 2612 and 2622 and are in contact with the first section 2612 and 2622 through the first and the second liner 291 and 292 respectively.

The first section 2612 of the first metal line 261 may be separated from a nearby metal line, such as the first section 2622 of the second metal line 262, by a first horizontal distance D1. The second section 2613 of the first metal line 261 may be separated from this nearby metal line, such as the second section 2623 of the second metal line 262, by a second horizontal distance D2. D1 may be larger than D2 and in one embodiment may be between about 120% and about 140% of D2. Overall, the first metal line 261 and the second metal line 262 may be centrally separated by a distance DO, here distance DO refers to a distance between a mid-point of the width of the top section 2613 of the first metal line 261 and a mid-point of the width of the top section 2623 of the second metal line 262, and distance DO may be at least 10 nm. The increase in horizontal distance D1, compared with D2, helps reduce a capacitance which otherwise would be formed by the first metal line 261 and the nearby metal line. In one embodiment, the nearby metal line may be the second metal line 262. In another embodiment, the nearby metal line may be a metal line having a substantially uniform width albeit a slightly slanted sidewall, such as a metal line 563 illustrated in FIG. 5 which will be described below in more details.

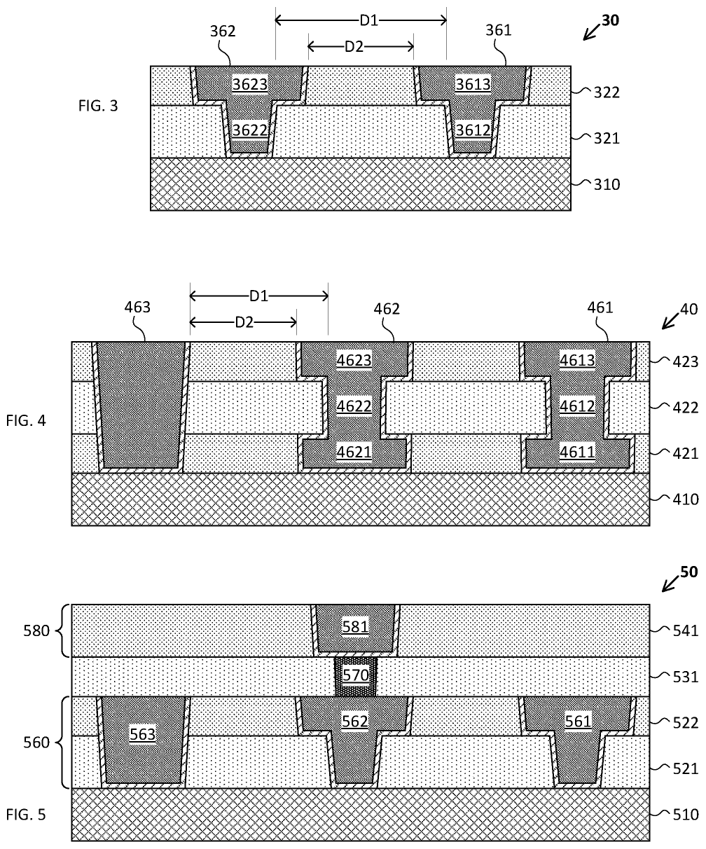

FIG. 3 is a demonstrative illustration of cross-sectional view of a semiconductor structure according to one embodiment of present invention. More particularly, embodiments of present invention provide a semiconductor structure 30, such as an interconnect structure, that includes a metal level, and the metal level includes a first metal line 361 and a second metal line 362. Like the semiconductor structure 20, the first and the second metal line 361 and 362 have a first section 3612 and 3622 respectively in a first dielectric layer 321, a second section 3613 and 3623 respectively in a second dielectric layer 322 and respectively on top of the first section 3612 and 3622. The first section 3612 and 3622 have a width that is narrower than a width of the second section 3613 and 3623. The first sections 3612 and 3622 are separated by a first horizontal distance D1 and the second sections 3613 and 3623 are separated by a second horizontal distance D2 and D2 is smaller than D1. Unlike the semiconductor structure 20, the first and the second metal line 361 and 362 do not include a third section underneath the first section 3612 and 3622 and are formed directly on top of a supporting structure 310.

FIG. 4 is a demonstrative illustration of cross-sectional view of a semiconductor structure according to yet another embodiment of present invention. More particularly, embodiments of present invention provide a semiconductor structure 40, or an interconnect structure, that includes a supporting structure 410, a first, a second, and a third dielectric layer 421, 422, and 423. Like the first metal line 161 and the second metal line 162 as being described above and demonstratively illustrated in FIG. 1E, the semiconductor structure 40 includes a first metal line 461 having a first section 4611, a second section 4612, and a third section 4613; and a second metal line 462 having a first section 4621, a second section 4622, and a third section 4623. Unlike the semiconductor structure 10, the semiconductor structure 40 further includes a third metal line 463 that may have a substantially uniform width, unlike the first and the second metal line 461 and 462, albeit slightly slanted sidewalls due to the nature of processing such as etch process. The third metal line 463 may be separated at a middle section from the second section 4622 of the second metal line 462 by a first horizontal distance D1 and separated at a top section from the third section 4623 of the second metal line 463 by a second horizontal distance D2. The first horizontal distance D1 is larger than the second horizontal distance D2.

FIG. 5 is a demonstrative illustration of cross-sectional view of a semiconductor structure according to yet another embodiment of present invention. More particularly, embodiments of present invention provide a semiconductor structure 50, or an interconnect structure, that includes a first metal level 560 formed on top of a supporting structure 510, an interlevel dielectric (ILD) layer 531 on top of the first metal level 560, and a second metal level 580 on top of the ILD layer 531.

The first metal level 560 may include a first and a second dielectric layer 521 and 522, with a first, a second, and a third metal lines 561, 562, and 563 formed therein. The second metal level 580 may include at least one metal line 581 formed in a dielectric layer 541. In one embodiment, the metal line 581 in the second metal level 580 may be connected to a metal line such as the second metal line 562 in the first metal level 560 through a conductive via 570. The conductive via 570 may be formed in the ILD layer 531.

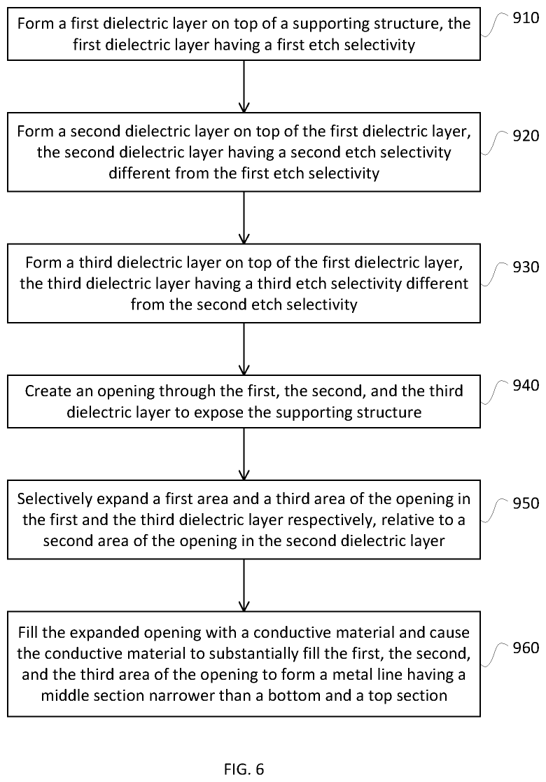

FIG. 6 is a demonstrative illustration of a flow-chart of a method of manufacturing a semiconductor structure according to embodiments of present invention. The method includes (910) forming a first dielectric layer on top of a supporting structure, the first dielectric layer having a first etch selectivity; (920) forming a second dielectric layer on top of the first dielectric layer, the second dielectric layer having a second etch selectivity different from the first etch selectivity; (930) forming a third dielectric layer on top of the first dielectric layer, the third dielectric layer having a third etch selectivity different from the second etch selectivity; (940) creating an opening through the first, the second, and the third dielectric layer to expose the supporting structure; (950) selectively expanding a first area and a third area of the opening in the first and the third dielectric layer respectively, relative to a second area of the opening in the second dielectric layer; and (960) filling the expanded opening with a conductive material and cause the conductive material to substantially fill the first, the second, and the third area of the opening to form a metal line having a middle section narrower than a bottom section and a top section.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a metal level comprising a metal line, the metal line comprising a bottom section having a first width, a middle section having a second width, and a top section having a third width,
wherein the second width of the middle section is narrower than the first width of the bottom section and is narrower than the third width of the top section.

2. The semiconductor structure of claim 1, further comprising a liner conformally lining sidewalls of the top section, sidewalls of the middle section, sidewalls of the bottom section, and a bottom surface of the bottom section.

3. The semiconductor structure of claim 2, wherein the metal line comprises copper and the liner comprises titanium-nitride (TiN).

4. The semiconductor structure of claim 1, wherein the bottom section is embedded in a first dielectric layer, the middle section is embedded in a second dielectric layer, and the top section is embedded in a third dielectric layer, wherein the second dielectric layer has a material composition that is different from material compositions of the first and the third dielectric layer.

5. The semiconductor structure of claim 4, wherein the second dielectric layer has an etch selectivity that is different from etch selectivity of the first and the third dielectric layer.

6. The semiconductor structure of claim 1, wherein the metal line is a first metal line, further comprising a second metal line parallel to the first metal line, wherein a first horizontal distance between the middle section of the first metal line and a middle section of the second meta line is larger than a second horizontal distance between the top section of the first metal line and a top section of the second metal line.

7. The semiconductor structure of claim 6, wherein the second metal line, from a top to a bottom thereof, has a substantially uniform width.

8. The semiconductor structure of claim 6, wherein the middle section of the second metal line is narrower than the top section of the second metal line.

9. The semiconductor structure of claim 1, wherein the second width of the middle section is between about 25% and about 50% of the first width of the bottom section, and wherein the first width of the bottom section is smaller than the third width of the top section.

10. An interconnect structure comprising:
a metal level comprising a metal line, the metal line comprising a first section having a first width and a second section having a second width, the second section being directly on top of the first section; and
a liner lining a bottom surface and sidewalls of the first section and lining sidewalls of the second section,
wherein the first width of the first section is narrower than the second width of the second section.

11. The interconnect structure of claim 10, wherein the metal line is a first metal line, further comprising:
a second metal line parallel to the first metal line, the second metal line having a first section and a second section, the second section of the second metal line being directly on top of the first section of the second metal line,
wherein a first horizontal distance between the first section of the first metal line and the first section of the second meta line is larger than a second horizontal distance between the second section of the first metal line and the second section of the second metal line.

12. The interconnect structure of claim 11, wherein the first metal line and the second metal line are centrally separated by at least 10 nm.

13. The interconnect structure of claim 10, wherein the metal line further comprises a third section directly underneath the first section, the third section having a third width that is wider than the first width of the first section and being in contact with the first section through the liner.

14. The interconnect structure of claim 10, wherein the metal level is a first metal level, further comprising a second metal level having at least one metal line, and the at least one metal line is conductively connected to the metal line of the first metal level through a conductive via.

15. The interconnect structure of claim 11, wherein the first horizontal distance is between about 120% and about 140% of the second horizontal distance.

16. A method of forming a semiconductor structure comprising:
forming a first dielectric layer on top of a supporting structure;
forming a second dielectric layer on top of the first dielectric layer;
forming a third dielectric layer on top of the second dielectric;
creating an opening that has a first area in the first dielectric layer, a second area in the second dielectric layer, and a third area in the third dielectric layer;
selectively etching the first and the third dielectric layer, relative to the second dielectric layer, thereby horizontally expanding the first area and the third area of the opening respectively to create an expanded opening; and
filling the expanded opening with a conductive material to form a metal line,
wherein the metal line has a bottom section with a first width, a middle section with a second width, and a top section with a third width, the second width being smaller than the first width and the third width.

17. The method of claim 16, wherein filling the expanded opening with the conductive material further comprises applying a metal reflow process to cause the conductive material to substantially fill the first area of the opening in the first dielectric layer.

18. The method of claim 16, further comprising, after creating the expanded opening, conformally forming a liner lining an inner surface of the expanded opening against the first, the second, and the third dielectric layer and against a top surface of an exposed portion of the supporting structure.

19. The method of claim 18, wherein the liner is either a conformal titanium-nitride (TiN) layer or a conformal tantalum-nitride (TaN) layer.

20. The method of claim 19, wherein the first and the third dielectric layer comprises silicon-oxide (SiO₂) and the second dielectric layer comprises silicon-nitride (SiN).
